(19) United States
(12) Patent Application Publication
(10) Pub. No.: US 2025/0257449 A1
(43) Pub. Date: Aug. 14, 2025

(54) TWO-DIMENSIONAL MATERIAL BASED STRUCTURE AND METHOD OF FORMING THE SAME

(71) Applicant: National University of Singapore, Singapore (SG)

(72) Inventors: Jin Feng LEONG, Singapore (SG); Jianan LI, Singapore (SG); Baoshan TANG, Singapore (SG); Aaron Voon-Yew THEAN, Singapore (SG)

(21) Appl. No.: 19/050,398

(22) Filed: Feb. 11, 2025

Related U.S. Application Data
(60) Provisional application No. 63/552,712, filed on Feb. 13, 2024.

(51) Int. Cl. C23C 16/22; C23C 16/02; C23C 16/06

(52) U.S. Cl. CPC C23C 16/22; C23C 16/0272; C23C 16/06

(57) ABSTRACT

Various embodiments may relate to a method of forming a two-dimensional (2D) material based structure. The method may include forming a self-assembled monolayer (SAM) on an underlying structure. The method may also include forming a two-dimensional material (2DM) film. The 2DM film may be suspended over the self-assembled monolayer (SAM), the two-dimensional (2DM) film separated from the self-assembled monolayer (SAM) by a solvent or a fluid. The method may further include bringing the two-dimensional material (2DM) film and the self-assembled monolayer (SAM) in contact with each other.

### CROSS-REFERENCE TO RELATED APPLICATION

This application claims the benefit of priority of U.S. application No. 63/552,712 filed Feb. 13, 2024, the contents of which are hereby incorporated by reference in its entirety for all purposes.

### TECHNICAL FIELD

Various embodiments of this disclosure may relate to a two-dimensional material based structure. Various embodiments of this disclosure may relate to a method of forming a two-dimensional material based structure.

### BACKGROUND

Two-dimensional materials (2DMs) have been under intense study due to their atomically thin thicknesses with diverse material properties ranging from superconductivity, exceptionally strong interaction with light, and absence of mobility degradation in sub-nanometer regimes. The increasing maturity of wafer-level deposition of 2DMs could enable the unique properties of 2DMs to be applied to various applications, which may include quantum computing, neuromorphic computing, electronics, and sensors. Currently, deposition of 2DMs may include transfer of chemical vapor deposition (CVD), physical vapor deposition (PVD), and molecular beam epitaxy (MBE) grown films, as well as solution-processed deposition of 2DM films via Langmuir deposition (i.e., Langmuir-Schaeffer or Langmuir-Blodgett), spin-coating and printing. However, ensuring the high-quality deposition of these films has been a challenge. For CVD-grown films, there may be potential formation of wrinkles, cracks, and tears, which may arise due to the uneven surface energy induced from the trapped air and water between the 2DMs and the underlying substrate. Similarly, solution-based deposition of 2DMs also faces issues, as the substrate's surface energy relative to that of the solvent of the 2DM suspension can influence the coverage and uniformity of the 2DM film deposition. Air and water may be trapped between the more hydrophobic parts of the substrate and interface of the solvent, which may impede the contact of 2DMs with the underlying substrate for efficient deposition.

### SUMMARY

Various embodiments may relate to a method of forming a two-dimensional (2D) material based structure. The method may include forming a self-assembled monolayer (SAM) on an underlying structure. The method may also include forming a two-dimensional material (2DM) film. The 2DM film may be suspended over the self-assembled monolayer (SAM), the two-dimensional (2DM) film separated from the self-assembled monolayer (SAM) by a solvent or a fluid. The method may further include bringing the two-dimensional material (2DM) film and the self-assembled monolayer (SAM) in contact with each other.

Various embodiments may relate to a two-dimensional (2D) material based structure formed by any method as described herein.

### BRIEF DESCRIPTION OF THE DRAWINGS

In the drawings, like reference characters generally refer to the same parts throughout the different views. The drawings are not necessarily drawn to scale, emphasis instead generally being placed upon illustrating the principles of various embodiments. In the following description, various embodiments of the invention are described with reference to the following drawings.

FIG. 1 shows a general illustration of a method of forming a two-dimensional (2D) material based structure according to various embodiments.

FIG. 2A shows a schematic in which a two-dimensional material (2DM) film is assembled or formed between two immiscible solvents (Solvent A and Solvent B) according to various embodiments.

FIG. 2B shows a schematic in which a mechanical scaffold is used to maintain a structural integrity of a two-dimensional material (2DM) film over a fluid according to various embodiments.

FIG. 2C shows a schematic in which an ejection tool is used to eject a two-dimensional material (2DM) suspended in a solvent over the self-assembled monolayer (SAM) according to various embodiments.

FIG. 3A shows a schematic in which the two-dimensional material (2DM) film assembled or formed between two immiscible solvents (Solvent A and Solvent B) is deposited onto the self-assembled monolayer (SAM), which is on the underlying substrate, by draining the solvent (i.e. Solvent B) underneath the 2DM film according to various embodiments.

FIG. 3B shows a schematic in which the two-dimensional material (2DM) film assembled or formed between two immiscible solvents (Solvent A and Solvent B) is deposited onto the self-assembled monolayer (SAM), which is on the underlying substrate, by raising the underlying substrate towards the 2DM film according to various embodiments.

FIG. 3C shows a schematic in which the two-dimensional material (2DM) film in contact with the scaffold is deposited onto the self-assembled monolayer (SAM), which is on the underlying substrate, by draining the fluid underneath the 2DM film according to various embodiments.

FIG. 3D shows a schematic in which the two-dimensional material (2DM) film in contact with the scaffold is deposited onto the self-assembled monolayer (SAM), which is on the underlying substrate, by lowering the scaffold using an alignment tool according to various embodiments.

FIG. 4 shows a schematic illustrating formation of a superlattice according to various embodiments.

FIG. 5 shows a schematic in which a self-assembled monolayer (SAM) is formed on a patterned underlying substrate before bringing the two-dimensional material (2DM) film onto the SAM according to various embodiments.

FIG. 6 shows a schematic comparing deposition of a two-dimensional material (2DM) film over an underlying structure functionalized with a self-assembled monolayer (SAM) according to various embodiments and a non-functionalized underlying structure.

FIG. 7 shows a schematic illustrating the removal of self-assembled monolayers (SAMs) with a wet etchant according to various embodiments.

### DESCRIPTION

The following detailed description refers to the accompanying drawings that show, by way of illustration, specific details and embodiments in which the invention may be practiced. These embodiments are described in sufficient detail to enable those skilled in the art to practice the invention. Other embodiments may be utilized and structural, logical, and electrical changes may be made without departing from the scope of the invention. The various embodiments are not necessarily mutually exclusive, as some embodiments can be combined with one or more other embodiments to form new embodiments.

Features that are described in the context of an embodiment may correspondingly be applicable to the same or similar features in the other embodiments. Features that are described in the context of an embodiment may correspondingly be applicable to the other embodiments, even if not explicitly described in these other embodiments. Furthermore, additions and/or combinations and/or alternatives as described for a feature in the context of an embodiment may correspondingly be applicable to the same or similar feature in the other embodiments.

In the context of various embodiments, the articles “a”, “an” and “the” as used with regard to a feature or element include a reference to one or more of the features or elements.

In the context of various embodiments, the term “about” or “approximately” as applied to a numeric value encompasses the exact value and a reasonable variance, e.g. within 10% of the specified value.

As used herein, the term “and/or” includes any and all combinations of one or more of the associated listed items.

By “comprising” it is meant including, but not limited to, whatever follows the word “comprising”. Thus, use of the term “comprising” indicates that the listed elements are required or mandatory, but that other elements are optional and may or may not be present.

By “consisting of” is meant including, and limited to, whatever follows the phrase “consisting of”. Thus, the phrase “consisting of” indicates that the listed elements are required or mandatory, and that no other elements may be present.

Embodiments described in the context of one of the structures are analogously valid for the other structures, embodiments described in the context of a method are analogously valid for a structure, and vice versa.

Various embodiments may address the abovementioned issues. Various embodiments may relate to a method for deposition of two-dimensional materials (2DMs) onto or over various substrates. A self-assembled monolayer (SAM) of organosilanes, thiols or phosphonates may be used to functionalize the underlying structure (e.g., substrate or top or exposed 2DM film of a stack). The self-assembled monolayer (SAM) may control the surface energy such that it would be suitable for the 2DMs deposition. By adopting the appropriate self-assembled monolayer (SAM) of organosilanes, thiols or phosphonates having a surface energy that is close to that of the 2DMs ink solvent, universal homogeneous deposition of 2DMs films may be performed onto the surface of any underlying structure. The SAM can subsequently be removed or retained depending on applications.

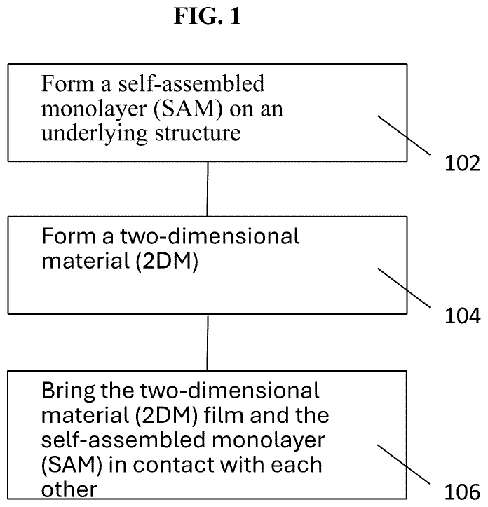

FIG. 1 shows a general illustration of a method of forming a two-dimensional (2D) material based structure according to various embodiments. The method may include, in 102, forming a self-assembled monolayer (SAM) on an underlying structure. The method may also include, in 104, forming a two-dimensional material (2DM) film. The 2DM film may be suspended over the self-assembled monolayer (SAM), the two-dimensional (2DM) film separated from the self-assembled monolayer (SAM) by a solvent or a fluid. The method may further include, in 106, bringing the two-dimensional material (2DM) film and the self-assembled monolayer (SAM) in contact with each other.

For avoidance of doubt, FIG. 1 is intended to provide a general illustration of various steps in accordance to various embodiments, and is not intended to be in sequence. For instance, step 102 may occur before, after or at the same time as step 104.

A “two-dimensional material” or “2DM” may refer to a crystalline material of a single layer of atoms/molecules, i.e., a monolayer. For avoidance of doubt, the term “two-dimensional (2DM) film” as described herein may include one or more monolayers of two-dimensional material (2DM). The two-dimensional material (2DM) film may include any appropriate material, e.g., a material selected from a group consisting of graphene, transition metal dichalcogenides (TMDC), MXenes, and transition metal oxides.

A “self-assembled monolayer” or “SAM” as described herein may refer to a single layer of organic molecules that spontaneously form as a highly ordered structure on a surface. The self-assembled monolayer (SAM) may include any appropriate molecule, e.g., an organosilane, a thiol or a phosphonate. The organosilane may, for instance, be 3-aminopropyltriethoxysilane (APTES), (3-mercaptopropyl)trimethyloxysilane, or 3-glycidoxypropyltrimethoxysilane.

The two-dimensional (2D) material based structure may alternatively be referred to as a “two-dimensional (2D) material based stack”, i.e., a stacked arrangement including at least one two-dimensional material (2DM) film. In various embodiments, the two-dimensional (2D) material based structure may be a superlattice including a plurality of two-dimensional material (2DM) films.

The term “underlying structure” may refer to a substrate or any other suitable structure, e.g., a composite structure including the substrate and one or more layers on or over the substrate. The term “underlying layer” may refer to the substrate or a layer of the composite structure in which the self-assembled monolayer (SAM) is formed on.

In various embodiments, the underlying structure may have a planar or flat surface on which the SAM is formed. In various other embodiments, the underlying structure may have a patterned surface. In various embodiments, by forming the 2DM film over a SAM on a patterned surface or patterned substrate, the 2DM film may also be patterned. Accordingly, the feature size of the printed 2DM film may be controlled based on the patterned substrate or patterned surface.

In various embodiments, forming the two-dimensional material (2DM) film suspended over the self-assembled monolayer (SAM) may include assembling or forming the two-dimensional material (2DM) film between the solvent and a further solvent immiscible with the solvent. The 2DM film may be formed from 2DM flakes suspended in the solvent. Bringing the two-dimensional material (2DM) film and the self-assembled monolayer (SAM) in contact with each other may include removing the solvent separating the two-dimensional material (2DM) film and the self-assembled monolayer (SAM). Alternatively, bringing the two-dimensional material (2DM) film and the self-assembled monolayer (SAM) in contact with each other may include moving or raising the self-assembled monolayer (SAM) and the underlying structure towards the two-dimensional material (2DM) film.

In various embodiments, forming the two-dimensional material (2DM) film suspended over the self-assembled monolayer (SAM) includes forming the two-dimensional material (2DM) film in contact with a scaffold. The 2DM film may be formed from 2DM flakes suspended in the solvent. The scaffold may be configured to maintain a structural integrity of the two-dimensional material (2DM) film. Bringing the two-dimensional material (2DM) film and the self-assembled monolayer (SAM) in contact with each other may include removing the fluid separating the two-dimensional material (2DM) film and the self-assembled monolayer (SAM). The fluid may be air or a liquid (e.g., the solvent). Bringing the two-dimensional material (2DM) film and the self-assembled monolayer (SAM) in contact with each other may include moving or raising the self-assembled monolayer (SAM) and the underlying structure towards the two-dimensional material (2DM) film. Alternatively, bringing the two-dimensional material (2DM) film and the self-assembled monolayer (SAM) in contact with each other may include moving the scaffold and the two-dimensional material (2DM) film towards the self-assembled monolayer (SAM) using an alignment tool.

In various embodiments, forming the two-dimensional material (2DM) film suspended over the self-assembled monolayer (SAM) may include ejecting the two-dimensional material (2DM) film suspended in the solvent over the self-assembled monolayer (SAM) using an ejection tool. The ejection tool may be a micropipette or a dropper. Bringing the two-dimensional material (2DM) film and the self-assembled monolayer (SAM) in contact with each other may include removing the solvent using spin-coating or evaporation.

In various embodiments, the two-dimensional material (2DM) film may be formed by chemical vapor deposition (CVD), molecular beam epitaxy (MBE) or physical vapor deposition (PVD).

As mentioned above, the two-dimensional (2D) material based structure may be a superlattice including a plurality of two-dimensional material (2DM) films. Various embodiments may relate to forming a stack including two 2DM films. In various embodiments, the method may further include forming a further self-assembled monolayer (SAM) on or over the two-dimensional material (2DM) film. The method may further include forming a further two-dimensional material (2DM) film suspended over the further self-assembled monolayer (SAM). The method may additionally include bringing the further two-dimensional material (2DM) film and the further self-assembled monolayer (SAM) in contact with each other. The self-assembled monolayer (SAM) and the further self-assembled monolayer (SAM) may include different materials, or may include a same material.

Various embodiments may relate to forming a stack including three or more 2DM films by repeating the steps as described above, i.e., forming a subsequent self-assembled monolayer (SAM) on or over a previously formed two-dimensional material (2DM) film, forming a subsequent two-dimensional material (2DM) film suspended over the subsequent self-assembled monolayer (SAM), and bringing the subsequent two-dimensional material (2DM) film and the subsequent self-assembled monolayer (SAM) in contact with each other.

In various embodiments, the method may also include forming one or more protective layers in contact with the two-dimensional material (2DM) film, the further two-dimensional material (2DM) film, and/or the subsequent two-dimensional material (2DM) film(s).

In various embodiments, the method may further include removing the self-assembled monolayer (SAM), the further self-assembled monolayer (SAM) and/or the subsequent two-dimensional material (2DM) film(s) via a wet etch process. The wet etch process may be carried out using hydrofluoric acid or potassium hydroxide.

In various embodiments, the underlying structure includes features with a dimension of less than 100 micrometers, e.g., 100 nanometers.

Various embodiments may relate to a two-dimensional (2D) material based structure formed by any method as described herein. Various embodiments may relate a two-dimensional (2D) material based structure including a self-assembled monolayer (SAM) on an underlying structure, and a two-dimensional material (2DM) film in contact with the self-assembled monolayer (SAM). In various other embodiments, the self-assembled monolayer (SAM) may be removed.

The method as described herein may minimize or reduce the defects created. In various embodiments, a concentration of defects formed from the method is less than 10¹² cm⁻³. In other words, a concentration of defects present in the two-dimensional material (2DM) film arising from the method as described herein (i.e., during deposition) may be less than 10¹² cm⁻³. Deposition may refer to the step of bringing the two-dimensional material (2DM) film and the self-assembled monolayer (SAM) in contact with each other. Various embodiments may reduce or minimize defects incurred from transfer of 2DM films by removing possibilities of trapped air between solvent (or fluid)/substrate interface due to surface energy differences.

Previous works have indicated the use of oxygen (O₂) plasma treatment on oxide-based substrates to improve hydrophilicity. However, this approach is non-universal and cannot be applied to substrate surfaces not reactive to oxygen plasma or cases in which the oxygen plasma can potentially damage the substrate surface.

Although previous works have disclosed that the self-assembled monolayers (SAMs) of organosilanes can be used for doping 2D films, these works did not highlight that SAMs can be used to enhance viability of deposition and transfer of 2D materials. Previous works also did not mention that SAMs can be used to form repeated stacks of 2D superlattices.

Currently, the industry is looking for a solution to effectively create monolithic three-dimensional (3D) stacks of two-dimensional materials for electronics. However, this is currently a challenge due to the following:
1. Lack of high-quality, low-temperature (<400° C.) growth methodologies for two-dimensional materials.
2. Lack of effective solution for wafer-scale, high throughput, and defect-free transfer of two-dimensional materials.

A potential solution may be to use solution-processed 2DM films formed from spin-coating or Langmuir deposition methods that can be processed at low temperatures as well as offer unique physical phenomena that could be applied to emerging electronics. Another solution is to find effective methods to reduce defects (i.e. wrinkles, tears, and cracks) formed from the transfer process of 2DMs.

Various embodiments may aim to ameliorate the substrate effects encountered by solution-based deposition as well as transfer of 2DM films to realize monolithic 3D stacks currently of interest to semiconductor companies. By controlling the surface energy of the underlying substrate surface with SAM of organosilanes, thiols or phosphonates, the surface energy differences between the solvent/fluid holding the 2DM and the functionalized underlying structure may be reduced, enabling uniform deposition across various surfaces. By selection of a solvent/fluid and a SAM in which the surface energies are close to each other, various embodiments may improve a uniformity and may reduce a defect concentration of the 2DM film deposited. This may also enable the stacking of 2DM films in a solution, which is currently hindered by the intrinsic hydrophobic surfaces of 2DMs.

Various embodiments may reduce or minimize defects incurred from transfer of 2DM films by removing possibilities of trapped air between water/substrate interface due to surface energy differences.

Various embodiments may be suitable to develop a monolithic three dimensional (3D) stacked, gate-all-around complementary field effect transistor. Various embodiments may be applied to manufacture superlattice stacks of solution-processed two-dimensional materials necessary for this endeavor. Various embodiments may be used to fabricate non-volatile memories for artificial intelligence compute-in-memory (aCiM) architecture. Various embodiments may be used to extend the spin-coating methodology to be applied to other two-dimensional materials that have colloidal stability in other solvents which have a high surface energy difference with the underlying substrate that hinders effective deposition of two-dimensional materials for film formation.

The method may generally be divided into three parts, namely the film formation step, the functionalization of the underlying layer, and the deposition process.

### Film Formation

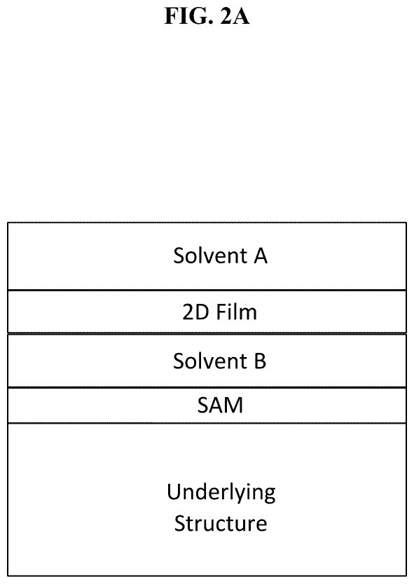

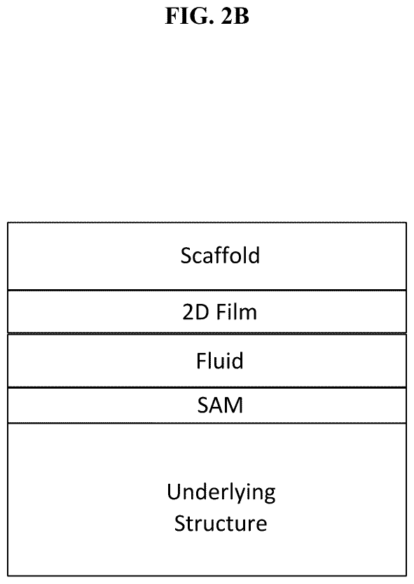

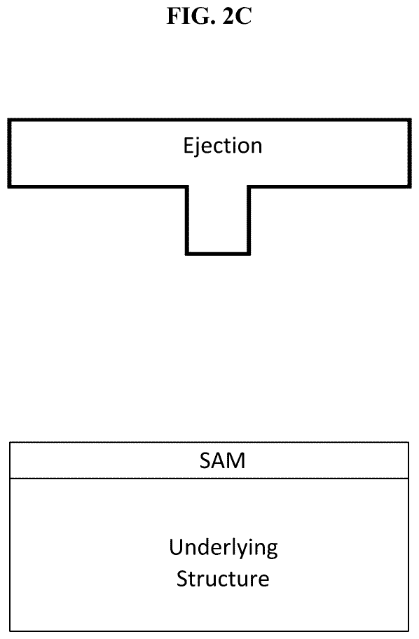

FIG. 2A shows a schematic in which a two-dimensional material (2DM) film is assembled or formed between two immiscible solvents (Solvent A and Solvent B) according to various embodiments. Solvent A and Solvent B may hold the 2DM film in between. Solvent B may be between the 2DM film and the SAM, and may initially separate the 2D film from the SAM (i.e., before deposition). The SAM may be on an underlying structure.

In various embodiments, the two-dimensional material (2DM) film may be delaminated in a fluid/solvent and may be formed or assembled on a surface of the fluid/solvent. FIG. 2B shows a schematic in which a mechanical scaffold is used to maintain a structural integrity of a two-dimensional material (2DM) film over a fluid according to various embodiments. The fluid may be a gas/gas mixture (e.g., air) or a liquid (e.g., solvent). The fluid may be between the 2DM film and the SAM, and may initially separate the 2D film from the SAM (i.e., before deposition). The SAM may be on an underlying structure.

FIG. 2C shows a schematic in which an ejection tool is used to eject a two-dimensional material (2DM) suspended in a solvent over the self-assembled monolayer (SAM) according to various embodiments. The SAM may be on an underlying structure. The ejection tool may, for instance, be a micropipette or a dropper etc. The 2DM film ejected in this manner over the underlying structure may be allowed to dry either by spin-coating or evaporation.

### Functionalization of Underlying Layer Or Structure

The underlying structure or underlying layer may be functionalized with a self-assembled monolayer (SAM) of organosilanes, thiols or phosphonates to minimize or reduce the surface energy difference between the underlying layer/structure with a common fluid/solvent used for film suspension, e.g., water. Various organosilanes, thiols or phosphonates may be applied for different fluids/solvents or 2DMs with the goal of minimizing or reducing the surface energy differences between the fluids/solvents and the 2DMs for effective spreading (i.e. contact angle minimization) and uniform deposition. Examples of organosilanes which may possibly be used may include 3-aminopropyltriethoxysilane (APTES), (3-mercaptopropyl)trimethyloxysilane, or 3-glycidoxypropyltrimethoxysilane.

### Deposition

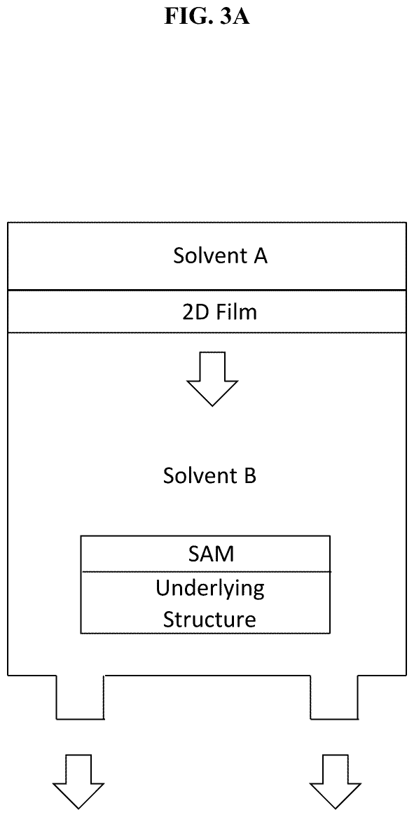

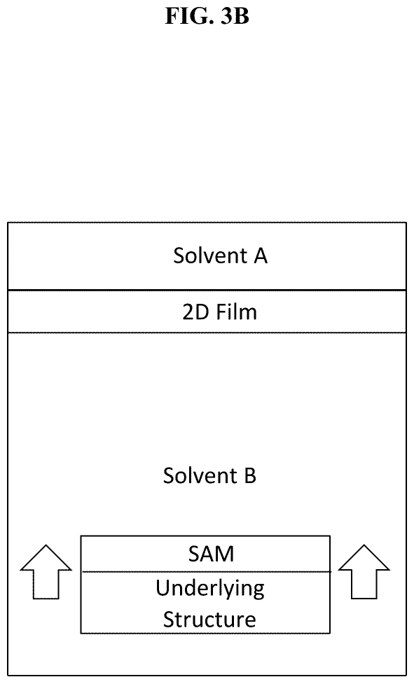

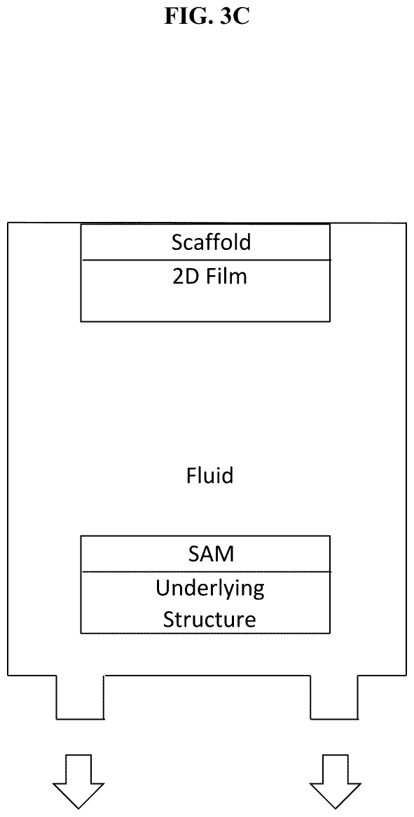

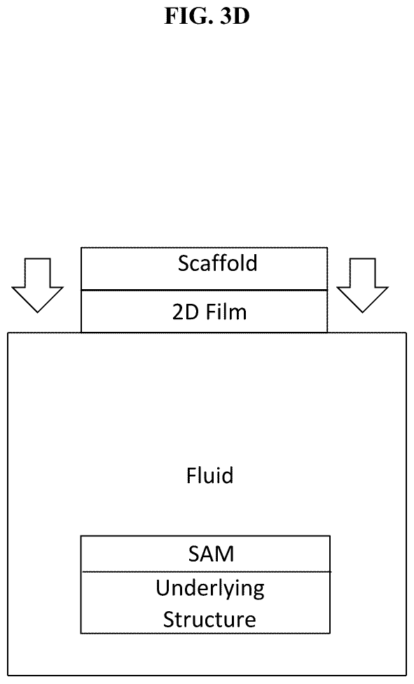

FIG. 3A shows a schematic in which the two-dimensional material (2DM) film assembled or formed between two immiscible solvents (Solvent A and Solvent B) is deposited onto the self-assembled monolayer (SAM), which is on the underlying substrate, by draining the solvent (i.e. Solvent B) underneath the 2DM film according to various embodiments. FIG. 3B shows a schematic in which the two-dimensional material (2DM) film assembled or formed between two immiscible solvents (Solvent A and Solvent B) is deposited onto the self-assembled monolayer (SAM), which is on the underlying substrate, by raising the underlying substrate towards the 2DM film according to various embodiments. FIG. 3C shows a schematic in which the two-dimensional material (2DM) film in contact with the scaffold is deposited onto the self-assembled monolayer (SAM), which is on the underlying substrate, by draining the fluid underneath the 2DM film according to various embodiments. Alternatively, the two-dimensional material (2DM) film in contact with the scaffold may be deposited onto the self-assembled monolayer (SAM) by raising the underlying substrate towards the 2DM film. FIG. 3D shows a schematic in which the two-dimensional material (2DM) film in contact with the scaffold is deposited onto the self-assembled monolayer (SAM), which is on the underlying substrate, by lowering the scaffold using an alignment tool according to various embodiments. The alignment tool may allow the 2DM film to be aligned onto the SAM. The alignment tool may, for instance, be a tool that recognizes (e.g., via machine learning) pre-patterned markers on the underlying substrate using optical images taken through a microscope.

### Mechanism

As mentioned above, by selection of a solvent/fluid and a SAM in which the surface energies are close to each other, various embodiments may improve a uniformity and may reduce a defect concentration of the 2DM film deposited. In this regard, Young's equation may be provided by:

$${γ}_{sg} = {γ}_{sl} + {γ}_{lg} cos θ$$

where γ_{sg} is the surface energy of the surface of the underlying structure, γₛₗ is the interfacial tension between the solvent/fluid and the underlying structure, and γ_{lg} is the surface tension of the solvent/fluid, and θ is the contact angle made between the solvent/fluid and the underlying structure. Generally speaking, when the solvent/fluid is water, a hydrophilic underlying structure may make a lower contact angle (closer to 0) with water than a hydrophobic one. A surface of the underlying structure functionalized with SAM may result in a contact angle with water lower than that of a structure without SAM.

### Formation of Superlattices

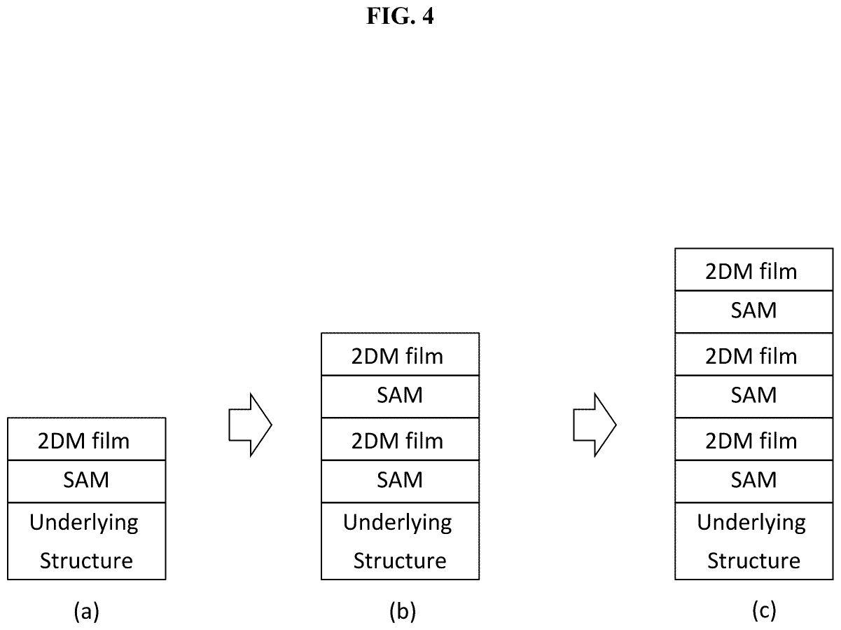

Superlattice made of 2D films assembled by two immiscible solvents can be formed. FIG. 4 shows a schematic illustrating formation of a superlattice according to various embodiments. The underlying structure may first functionalized with a SAM. Then, the 2DM film suspended between two solvents may then be deposited onto the substrate by draining the solvent below the 2DM film, as shown in (a) of FIG. 4. Another SAM film may be formed on the 2DM film, before another 2DM film is deposited, as shown in (b) of FIG. 4. The process of functionalization followed by the 2DM film formation and deposition can be repeated to achieve a multilayer stack of 2DM, as shown in (c) of FIG. 4.

If different solvents are used, the SAM of organosilanes, thiols or phosphonates may be varied accordingly with the target of minimizing or reducing the surface energy differences between the solvent and the SAM.

Deposition of Solution-Processed Films on Substrates with Varying Materials

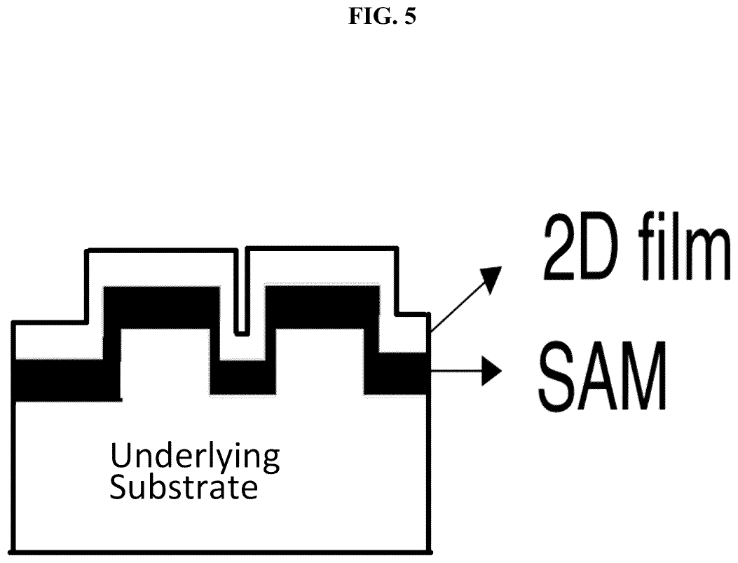

Micrometer or nanometer-sized features may be made on a substrate before the 2DM deposition process. FIG. 5 shows a schematic in which a self-assembled monolayer (SAM) is formed on a patterned underlying substrate before bringing the two-dimensional material (2DM) film onto the SAM according to various embodiments. In various embodiments, the SAM may be formed on an underlying structure in which the micrometer or nanometer-sized features are made from different materials. With the functionalization of the entire substrate surface using a SAM of organosilanes, thiols or phosphonates, 2DM films assembled by two immiscible solvents may be deposited over the substrate with higher and more uniform coverage across all micrometer or nanometer-sized features compared to substrates that have not undergone the mentioned functionalization process.

Reduction or Minimization of Wrinkles, Tears or Cracks from Transfer of Chemical Vapor Deposition (CVD)/Physical Vapor Deposition (PVD)/Molecular Beam Epitaxy (MBE) Grown Films onto Underlying Structure

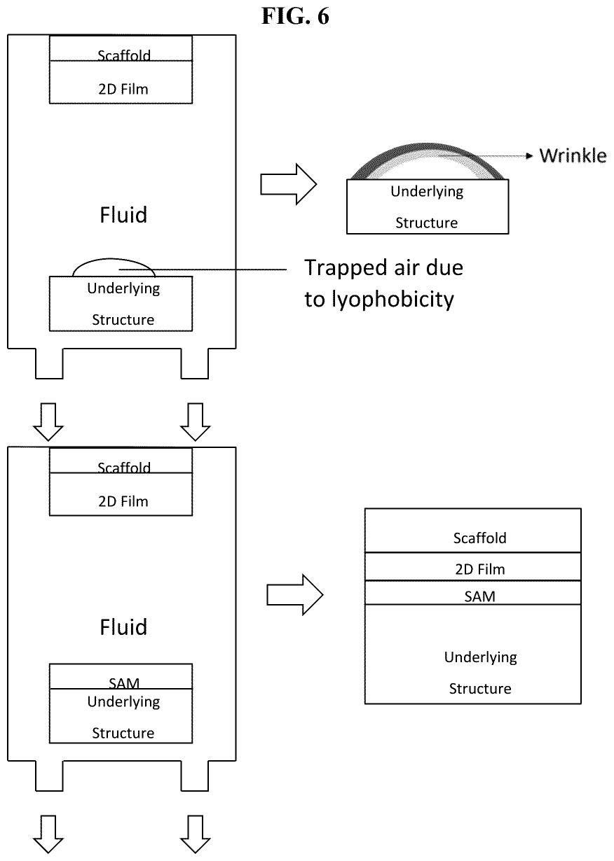

FIG. 6 shows a schematic comparing deposition of a two-dimensional material (2DM) film over an underlying structure functionalized with a self-assembled monolayer (SAM) according to various embodiments and a non-functionalized underlying structure. For the deposition of CVD/PVD/MBE-grown 2DM films supported by a mechanical scaffold suspended in fluid, the proposed functionalization using a SAM of organosilanes, thiols or phosphonates may lead to a more uniform spreading (i.e. low contact angle) of fluid/solvent on the underlying structure during deposition, and may prevent or reduce air trapping due to hydrophilicity of the functionalized underlying substrate. This may lead to the minimization or reduction of wrinkles, tears, or cracks during the transfer of CVD/PVD/MBE films.

### Spin-Coating of 2DM Over Underlying Structure

Functionalization of the underlying structure by a SAM of organosilanes, thiols or phosphonates may minimize or reduce the surface energy differences between the underlying structure and the suspension with the 2DM flakes and the solvent. Thus, the spreading of the 2DM flake suspension may be maximized or increased as it drops onto the underlying structure. This may improve the coverage and deposition efficiency of the spin-coating process with 2DM flake suspensions, as less ink (suspension) may be spun out with the acceleration of the spin rate.

### Selective Etching of SAM

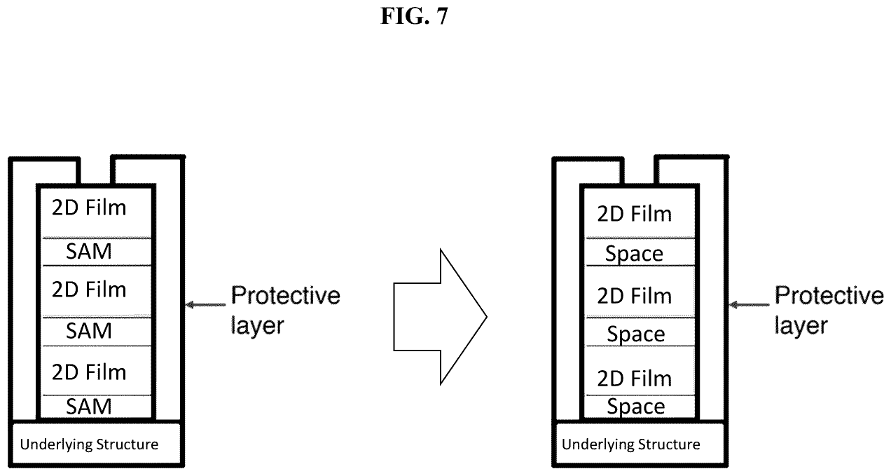

The SAMs of organosilanes, thiols or phosphonates can be selectively removed with etching processes. A protective layer including a protective material, such as a metal that is non-reactive to wet etchants, may be formed a 2DM based structure to serve as a hard mask holding onto the 2DM layers while the SAMs are removed with wet etchant. The wet etchant may be selected such that it is able to selectively etch the SAM without damaging the 2DM. The wet etchant may include, but may not be limited to, dilute hydrofluoric acid and potassium hydroxide. FIG. 7 shows a schematic illustrating the removal of self-assembled monolayers (SAMs) with a wet etchant according to various embodiments. A protective structure may be formed to hold the 2DM films while the SAMs are removed. Upon removal of the SAMs, neighbouring 2DM films of the 2DM based structure may be separated by a space.

Various embodiments may relate to a method to minimize or reduce the surface energy differences between the underlying structure and the solvent holding the 2DM to enable deposition over various kinds of substrates. Various embodiments may also be used to control the feature size of the printed 2DM films, and may also be used to minimize or reduce defects obtained from the transfer of 2DM films.

The functionalization of the substrate with a silane-based organic molecule, a thiol or a phosphonate that reduces or minimizes surface energy differences between the deposition solvent and the substrate may ensure the high efficiency of solution processed 2DMs together with excellent coverage and uniformity.

In addition, the functionalization of an underlying structure 2DM film may ameliorate the surface energy differences between the underlying 2DM film and the solvent holding the 2DM film to be stacked over the underlying 2DM film, which may enable repeated stacking of 2DM films for superlattice formation.

Also, the chemical functionalization of the substrate may easily be scalable to the wafer-level deposition of 2DM films.

Further, the functionalization of the underlying structure may also be applied to the transfer of 2DMs as it is able to mitigate surface energy differences on the underlying structure.

Additionally, the functionalization of the underlying structure may increase the spreading of 2DM-based ink before the spin-coating process, thus improving rate of evaporation of the solvent and eventual deposition of 2DM flakes/films over the underlying structure.

The SAMs may be removed with selective etching processes, depending on the eventual application of the deposited 2DM films.

One challenge may be the expected introduction of surface charge transfer doping in 2DM films from the underlying functionalization. In this regard, various embodiments may involve application of doping techniques (e.g. remote plasma oxidation, atomic substitution) to reverse or reduce surface charge transfer doping effects in the 2DM films.

1. A method of forming a two-dimensional (2D) material based structure, the method comprising:
forming a self-assembled monolayer (SAM) on an underlying structure;
forming a two-dimensional material (2DM) film suspended over the self-assembled monolayer (SAM), the two-dimensional (2DM) film separated from the self-assembled monolayer (SAM) by a solvent or a fluid; and
bringing the two-dimensional material (2DM) film and the self-assembled monolayer (SAM) in contact with each other.

2. The method according to claim 1,
wherein forming the two-dimensional material (2DM) film suspended over the self-assembled monolayer (SAM) includes assembling the two-dimensional material (2DM) film between the solvent and a further solvent immiscible with the solvent.

3. The method according to claim 2,
wherein bringing the two-dimensional material (2DM) film and the self-assembled monolayer (SAM) in contact with each other includes removing the solvent separating the two-dimensional material (2DM) film and the self-assembled monolayer (SAM).

4. The method according to claim 2,
wherein bringing the two-dimensional material (2DM) film and the self-assembled monolayer (SAM) in contact with each other comprises moving or raising the self-assembled monolayer (SAM) and the underlying structure towards the two-dimensional material (2DM) film.

5. The method according to claim 1,
wherein forming the two-dimensional material (2DM) film suspended over the self-assembled monolayer (SAM) comprises forming the two-dimensional material (2DM) film in contact with a scaffold.

6. The method according to claim 5,
wherein the scaffold is configured to maintain a structural integrity of the two-dimensional material (2DM) film.

7. The method according to claim 6,
wherein bringing the two-dimensional material (2DM) film and the self-assembled monolayer (SAM) in contact with each other comprises removing the fluid separating the two-dimensional material (2DM) film and the self-assembled monolayer (SAM).

8. The method according to claim 7,
wherein the fluid is air or a liquid.

9. The method according to claim 5,
wherein bringing the two-dimensional material (2DM) film and the self-assembled monolayer (SAM) in contact with each other comprises moving or raising the self-assembled monolayer (SAM) and the underlying structure towards the two-dimensional material (2DM) film.

10. The method according to claim 5,
wherein bringing the two-dimensional material (2DM) film and the self-assembled monolayer (SAM) in contact with each other comprises moving the scaffold and the two-dimensional material (2DM) film towards the self-assembled monolayer (SAM) using an alignment tool.

11. The method according to claim 1,
wherein forming the two-dimensional material (2DM) film suspended over the self-assembled monolayer (SAM) comprises ejecting the two-dimensional material (2DM) film suspended in the solvent over the self-assembled monolayer (SAM) using an ejection tool.

12. The method according to claim 11,
wherein the ejection tool is a micropipette or a dropper.

13. The method according to claim 11,
wherein bringing the two-dimensional material (2DM) film and the self-assembled monolayer (SAM) in contact with each other comprises removing the solvent using spin-coating or evaporation.

14. The method according to claim 1,
wherein the self-assembled monolayer (SAM) comprises an organosilane, a thiol or a phosphonate.

15. The method according to claim 14,
wherein the organosilane is 3-aminopropyltriethoxysilane (APTES), (3-mercaptopropyl)trimethyloxysilane, or 3-glycidoxypropyltrimethoxysilane.

16. The method according to claim 1,
wherein the two-dimensional material (2DM) film comprises a material selected from a group consisting of graphene, transition metal dichalcogenides (TMDC), MXenes, and transition metal oxides.

17. The method according to claim 1,
wherein the two-dimensional material (2DM) film is formed by chemical vapor deposition (CVD), molecular beam epitaxy (MBE) or physical vapor deposition (PVD).

18. The method according to claim 1, further comprising:
forming a further self-assembled monolayer (SAM) on the two-dimensional material (2DM) film;
forming a further two-dimensional material (2DM) film suspended over the further self-assembled monolayer (SAM); and
bringing the further two-dimensional material (2DM) film and the further self-assembled monolayer (SAM) in contact with each other.

19. The method according to claim 18,
wherein the self-assembled monolayer (SAM) and the further self-assembled monolayer (SAM) comprise different materials.

20. The method according to claim 18,
wherein the self-assembled monolayer (SAM) and the further self-assembled monolayer (SAM) comprise a same material.

21. The method according to claim 18, further including:
forming one or more protective layers in contact with the two-dimensional material (2DM) film and the further two-dimensional material (2DM) film.

22. The method according to claim 21, further including:
removing the self-assembled monolayer (SAM) and the further self-assembled monolayer (SAM) via a wet etch process.

23. The method according to claim 22,
wherein the wet etch process is carried out using hydrofluoric acid or potassium hydroxide.

24. The method according to claim 1,
wherein the underlying structure includes features with a dimension of less than 100 micrometers.

25. The method according to claim 1,
wherein the underlying structure includes features with a dimension of less than 100 nanometers.

26. A two-dimensional (2D) material based structure formed according to a method comprising:
forming a self-assembled monolayer (SAM) on an underlying structure;
forming a two-dimensional material (2DM) film suspended over the self-assembled monolayer (SAM), the two-dimensional (2DM) film separated from the self-assembled monolayer (SAM) by a solvent or a fluid; and
bringing the two-dimensional material (2DM) film and the self-assembled monolayer (SAM) in contact with each other.

27. The two-dimensional (2D) material based structure according to claim 26, wherein a concentration of defects formed from the method is less than 10¹² cm⁻³.
